(19) United States
(12) Patent Application Publication
(10) Pub. No.: US 2025/0255007 A1
(43) Pub. Date: Aug. 7, 2025

(54) SURGE PROTECTION ELEMENT

(71) Applicant: OTOWA ELECTRIC CO., LTD., Osaka (JP)

(72) Inventors: Takatoshi Tojo, Hyogo (JP); Yoshimasa Tsujimoto, Hyogo (JP); Naoyuki Tsukamoto, Hyogo (JP); Shizuo Fujita, Hyogo (JP)

(21) Appl. No.: 19/009,334

(22) Filed: Jan. 3, 2025

(30) Foreign Application Priority Data
Feb. 7, 2024 (JP) 2024-016972

(51) Int. Cl. H10D 89/60; H10D 8/60; H10D 62/80

(52) U.S. Cl. CPC H10D 89/611; H10D 8/60; H10D 62/875

(57) ABSTRACT

The present invention provides a surge protection element that can smoothly handle an unnecessary current produced by a harmful pulse. A surge protection element 10 is the surge protection element 10 including a first electrode 11, an n-type semiconductor layer 12, a second electrode 13 sequentially joined in a designated direction. A portion at least from any position in the n-type semiconductor layer 12 toward the second electrode 13 in the designated direction is composed of a graded composition layer 12B, whereby in a state in which a voltage is not applied, a bandgap Eg of the portion gradually increases in the designated direction, and part of a conduction level Ec exceeding a Fermi level Ef in the portion gradually increases in the designated direction.

### BACKGROUND OF THE INVENTION

### Field of the Invention

The present invention relates to a surge protection element.

### Description of the Related Art

Many semiconductor devices including semiconductor circuits have been conventionally utilized. However, such a semiconductor device might fail if a voltage more than or equal to its operating voltage is applied thereto. Assumed causal overvoltage sources (harmful pulses) include surges caused by static electricity, a lightning stroke, or the like, electromagnetic pulses, intentional electromagnetic waves, and the like.

A semiconductor element 30 including a first n-type semiconductor layer 31A (ZnO), a second n-type semiconductor layer 31B (Zn_{0.50}Mg_{0.50}O) having a bandgap larger than that of the first n-type semiconductor layer, and a metal layer 32 (Pt, Au) has been conventionally known (see, for example, Japanese Patent Laid-Open No. 2022-174666, FIG. 4A).

### CITATION LIST

### Patent Literature

Patent Literature 1: Japanese Patent Application Laid-Open No. 2022-174666

### SUMMARY OF THE INVENTION

When a harmful pulse is applied to the above-described semiconductor element 30, an energy barrier 33 is produced between the first n-type semiconductor layer 31A and the second n-type semiconductor layer 31B (see FIG. 4B). The energy barrier raises a series resistance, leading to a problem in that an adverse influence is exerted on smooth handling of an unnecessary current produced by the harmful pulse.

In view of the above points, the present invention has an object to provide a surge protection element that can smoothly handle an unnecessary current produced by a harmful pulse.

A surge protection element of the present invention is a surge protection element including a first electrode, an n-type semiconductor layer, and a second electrode sequentially joined in a designated direction, in which a portion at least from any position in the n-type semiconductor layer toward the second electrode in the designated direction is composed of a graded composition layer, whereby in a state in which a voltage is not applied, a bandgap of the portion gradually increases in the designated direction, and part of a conduction level exceeding a Fermi level in the portion gradually increases in the designated direction.

In the surge protection element of the present invention, the bandgap of the portion composed of the graded composition layer gradually increases in the designated direction, and part of the conduction level exceeding the Fermi level in the graded composition layer gradually increases in the designated direction because at least part of the n-type semiconductor layer is composed of the graded composition layer. Even if a harmful pulse is applied to such a surge protection element, the energy barrier 33 as described above is not produced in the n-type semiconductor layer. This enables an unnecessary current produced by the harmful pulse to be smoothly handled.

Preferably, the graded composition layer of the n-type semiconductor layer is composed of a composite oxide or a composite nitride of at least two elements of an element A and an element B selected from the group consisting of Ga, In, Zn, Mg, Al, and Sn, or a combination thereof, and a content ratio of the element B to the element A gradually increases in the designated direction.

In the surge protection element of the present invention, the bandgap can gradually increase in the designated direction, and part of the conduction level exceeding the Fermi level can be gradually increased in the designated direction because the content ratio of the element B to the element A gradually increases in the designated direction.

In the surge protection element of the present invention, the n-type semiconductor layer preferably has a thickness of 5 to 1000 nm in the designated direction, and more preferably has a thickness less than or equal to 500 nm. Thus, a series resistance is reduced, and Joule heat produced when an unnecessary current is processed can be controlled.

### BRIEF DESCRIPTION OF THE DRAWINGS

FIG. 1 is a configuration diagram of a surge protection element of the present invention;

FIG. 2A is an energy band diagram of the surge protection element of the present invention before a voltage is applied thereto;

FIG. 2B is an energy band diagram of the surge protection element of the present invention when a voltage is applied thereto;

FIG. 3A is an energy band diagram of a modification of the surge protection element of the present invention before a voltage is applied thereto;

FIG. 3B is an energy band diagram of the modification of the surge protection element of the present invention when a voltage is applied thereto;

FIG. 4A is an energy band diagram of a conventional surge protection element before a voltage is applied thereto; and

FIG. 4B is an energy band diagram of the conventional surge protection element when a voltage is applied thereto.

### DETAILED DESCRIPTION OF THE INVENTION

A surge protection element 10 will be described in detail with reference to the drawings. The same or corresponding components have the same reference characters allotted, and description thereof will be omitted as appropriate in some cases.

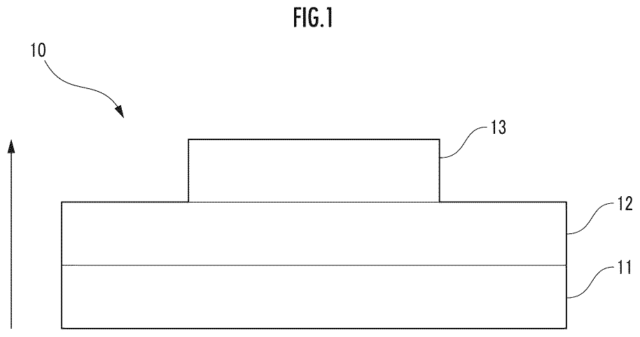

FIG. 1 shows the surge protection element 10 of the present invention. The surge protection element 10 includes a first electrode 11, an n-type semiconductor layer 12, and a second electrode 13. The first electrode 11, the n-type semiconductor layer 12, and the second electrode 13 are joined in this order in a designated direction (the direction of an upward arrow shown in FIG. 1).

A Schottky barrier SB is formed between the n-type semiconductor layer 12 and the second electrode 13. That is, the surge protection element 10 is a Schottky barrier diode, and therefore has a response speed higher than that of a p-n junction diode which is an element in which both majority carriers and minority carriers are involved.

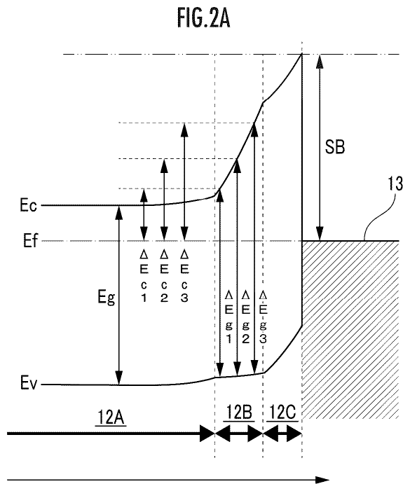

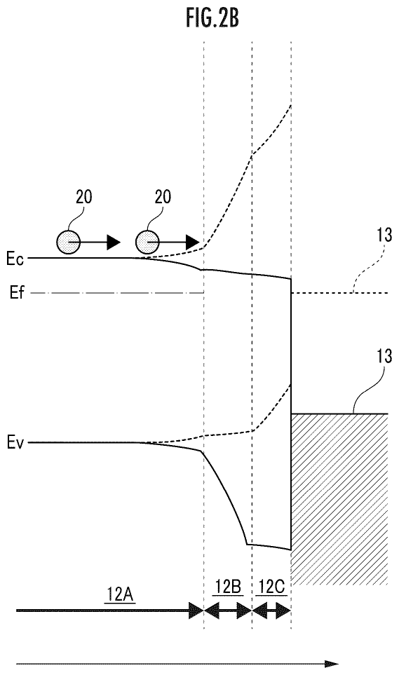

FIG. 2A is an energy band diagram in a state in which a voltage has not been applied to the surge protection element 10 of the present invention. In FIG. 2A, a dash-dotted line indicates a Fermi level Ef of the n-type semiconductor layer 12, and an upper solid line in the n-type semiconductor layer 12 indicates a conduction level Ec. In FIG. 2A, the Fermi levels Ef of the n-type semiconductor layer 12 and the second electrode 13 are shown in alignment. In the n-type semiconductor layer, a forbidden band which is an energy band in which there is no electron path exists at the center of a carrier distribution. Thus, free electrons at the conduction level of the n-type semiconductor layer 12 are located at an energy level higher than an energy level at which free electrons in metal are present, and a valence level Ev of the n-type semiconductor layer 12 is located at a low energy level. When the n-type semiconductor layer 12 and the second electrode 13 are joined, free electrons in the n-type semiconductor layer 12 move to the second electrode 13 side and decrease. The carrier distribution of the n-type semiconductor layer 12 at the junction is thereby changed, so that the Fermi level changes in position. However, the Fermi level itself does not move unless there is external application of a potential. Thus, energy levels of the conduction level and the valence level of the n-type semiconductor layer 12 at the junction change relatively with respect to the position of the Fermi level. The Schottky barrier SB is formed between the n-type semiconductor layer 12 and the second electrode 13 as described above. In the present embodiment, the bandgap Eg of the n-type semiconductor layer 12 is 3.4 eV, and the Schottky barrier SB between the n-type semiconductor layer 12 and the second electrode 13 is 2.8 eV.

The first electrode 11 is formed in a rectangular flat-plate shape having a pair of major surfaces opposite to each other as shown in FIG. 1. Ferrous metal is used as the material for the first electrode 11. Other than ferrous metal, aluminum-based metal, copper-based metal, or the like can also be used as the material for the first electrode 11. A metal substrate may be used as the first electrode 11. The use of the metal substrate as the first electrode 11 can further reduce the process (manufacturing) cost.

This point will be described in detail. In a case of forming a first electrode on one of upper and lower surfaces of the n-type semiconductor layer 12 and a second electrode on the other surface by vapor deposition or the like, the n-type semiconductor layer 12 is first deposited on a substrate (a substrate not limited to a metal substrate). Then, after forming either the first electrode or the second electrode, it is necessary to once separate the n-type semiconductor layer 12 from the substrate and form the other electrode on a separation surface of the n-type semiconductor layer 12. In contrast, in a case of using the metal substrate as the first electrode, it is only necessary to directly deposit the n-type semiconductor layer 12 immediately above the metal substrate and form the second electrode 13. Thus, the separation process can be omitted.

A substrate having a two-layered structure of an insulation layer (e.g., glass) and a metal layer may be used as the first electrode 11. With such a configuration, effects similar to the above-described effects can be obtained. When comparing the resistivity of a film with the resistivity of a bulk body, the resistivity of the film tends to be larger. Thus, the use of the metal substrate as the first electrode 11 enables an unnecessary current produced by a harmful pulse to be bypassed more promptly.

The n-type semiconductor layer 12 is joined to the first electrode 11 in the designated direction as shown in FIG. 1. Specifically, a compound film is caused to grow on the first electrode 11 by the mist chemical vapor deposition (CVD) method. Specifically, an organic metal (solid) containing a metal element that will form a desired film, for example, is dissolved by an organic solvent to obtain a raw material solution. Mist obtained by nebulizing the raw material solution by ultrasonic vibration is transferred to a high-temperature reaction container (at about 300 to 500° C.) while being diluted by nitrogen (N₂) gas to cause the compound film to grow on the first electrode 11 placed in the high-temperature reaction container. A gas flow rate is set at 5.0 L/min both for mist transfer carrier gas and dilution gas.

As a method of causing growth of the compound film, the metal organic chemical vapor deposition (MOCVD) method, for example, can be employed as a method other than the mist CVD method. As raw material gas at this time, gas obtained by vaporizing organic metal which is a raw material by hydrogen (H₂), nitrogen (N₂), or the like can be used. Alternatively, the sputtering method, vapor phase epitaxy (VPE) method, molecular beam epitaxy (MBE) method, or the like may be employed. The first electrode 11 and the n-type semiconductor layer 12 form an ohmic contact.

The n-type semiconductor layer 12 has a thickness of 5 to 1000 nm in the designated direction. The n-type semiconductor layer 12 more preferably has a thickness of 5 to 500 nm. When the n-type semiconductor layer 12 has a thickness less than or equal to 500 nm, the series resistance can be reduced, and at the same time, Joule heat can be controlled.

The n-type semiconductor layer 12 is composed of three layers of an initial layer 12A (on the first electrode 11 side in the n-type semiconductor layer 12), a graded composition layer 12B, and a final layer 12C (on the second electrode 13 side in the n-type semiconductor layer 12). The initial layer 12A is a low-resistance layer, and the final layer 12C is a high-resistance layer. In the present embodiment, the initial layer 12A, the graded composition layer 12B, the final layer 12C have thicknesses of 100 nm, 200 nm, and 100 nm, respectively. The initial layer 12A can have a layer thickness ranging from 1 to 200 nm, the graded composition layer 12B can have a layer thickness ranging from 1 to 200 nm, and the final layer 12C can have a layer thickness ranging from 1 to 200 nm. The sum of the thicknesses of the initial layer 12A, the graded composition layer 12B, and the final layer 12C is preferably less than or equal to 500 nm.

In the present embodiment, the initial layer 12A of the n-type semiconductor layer 12 is composed of an oxide of an element A. A portion from any position in the n-type semiconductor layer 12 in the designated direction toward the second electrode 13 is composed of the graded composition layer 12B. The graded composition layer 12B is composed of a composite oxide of the element A and the element B. In the present embodiment, the final layer 12C is composed of a composite oxide in which the content ratio of the element B to the element A is 8:2.

For example, the element A is zinc (Zn), and the element B is magnesium (Mg). That is, the initial layer 12A of the n-type semiconductor layer 12 is composed of zinc oxide (ZnO), and the graded composition layer 12B and the final layer 12C are composed of zinc magnesium oxide (ZnMgO).

In the graded composition layer 12B, the content ratio of the element B to the element A gradually increases in the designated direction. That is, the graded composition layer 12B is composed of zinc magnesium oxide (ZnMgO) in which the content ratio of magnesium (Mg) to zinc (Zn) gradually increases in the designated direction.

A transition of the content ratio of magnesium (Mg) to zinc (Zn) in the present embodiment is changed by a certain increment in the designated direction. The transition of the content ratio of magnesium (Mg) to zinc (Zn) may be such that the content ratio of magnesium (Mg) to zinc (Zn) is raised rapidly on the first electrode 11 side and such that the content ratio of magnesium (Mg) to zinc (Zn) is raised gently on the second electrode 13 side. Alternatively, the transition of the content ratio of magnesium (Mg) to zinc (Zn) may be such that the content ratio of magnesium (Mg) to zinc (Zn) is raised gently on the first electrode 11 side and such that the content ratio of magnesium (Mg) to zinc (Zn) is raised rapidly on the second electrode 13 side.

In the present embodiment, the content ratio of magnesium (Mg) to zinc (Zn) in the graded composition layer 12B is raised ultimately up to 8:2.

The transition of the content ratio of magnesium (Mg) to zinc (Zn) in the present embodiment is changed gradually (intermittently) in the designated direction. That is, the graded composition layer 12B is formed of a laminated structure of a plurality of layers in which the content ratio of magnesium (Mg) to zinc (Zn) is changed in the designated direction. The transition of the content ratio of magnesium (Mg) to zinc (Zn) may be changed continuously in the designated direction.

The graded composition layer 12B is formed such that the content ratio of magnesium (Mg) to zinc (Zn) gradually increases by changing a composition in raw solution in the growth process. For example, the composition, which is of Zn_{0.90}Mg_{0.10}O in the initial stage of growth, is then changed in concentration ratio to, in the order, Zn_{0.85}Mg_{0.15}O, Zn_{0.80}Mg_{0.20}O, Zn_{0.75}Mg_{0.25}O, . . . , and Zn_{0.20}Mg_{0.80}O, or changed by 0.05, thereby forming the graded composition layer 12B of a laminated structure of 16 layers.

In the case of the MOCVD method, the graded composition layer 12B formed such that the content ratio of magnesium (Mg) to zinc (Zn) gradually increases can be obtained by changing the concentration ratio of organic metal in carrier gas. In the case of the sputtering method, a plurality of sputtering targets different in composition are prepared, and a sputtering target is replaced with another sputtering target different in composition each time the single n-type semiconductor layer 12 is deposited. The graded composition layer 12B formed such that the content ratio of magnesium (Mg) to zinc (Zn) gradually increases can thereby be obtained.

Although the graded composition layer 12B of 16 layers is formed by changing the concentration ratio by 0.05 in the present embodiment, the concentration ratio may be changed by a value more than or equal to 0.05, such as by changing the concentration ratio by 0.10, for example, to form the graded composition layer 12B of eight layers, or the concentration ratio may be changed by a value less than or equal to 0.05, such as by changing the concentration ratio by 0.025 to form the graded composition layer 12B of 32 layers. The composition in raw solution in the growth process may be continuously changed in concentration ratio.

Although the composition in raw solution in the initial stage of growth of the graded composition layer 12B is Zn_{0.90}Mg_{0.10}O in the present embodiment, the composition in raw solution may be higher in Mg ratio, such as Zn_{0.80}Mg_{0.20}O, than Zn_{0.90}Mg_{0.10}O in the initial phase of growth, or the composition in raw solution may be lower in Mg ratio, such as Zn_{0.99}Mg_{0.01}O, than Zn_{0.90}Mg_{0.10}O in the initial phase of growth.

Although the composition in raw solution in the later stage of growth of the graded composition layer 12B is Zn_{0.20}Mg_{0.80}O in the present embodiment, the composition in raw solution may be lower in Mg ratio, such as Zn_{0.25}Mg_{0.75}, than Zn_{0.20}Mg_{0.80} in the later phase of growth.

As shown in FIG. 2A, the bandgap Eg gradually increases in the designated direction (in the direction of a right arrow) as ΔEg1, ΔEg2, and ΔEg3 in a portion composed of the graded composition layer 12B in the n-type semiconductor layer 12.

Part of the conduction level Ec exceeding the Fermi level Ef in the portion of the n-type semiconductor layer 12 composed of the graded composition layer 12B is composed so as to gradually increase in the designated direction (in the direction of the right arrow) as ΔEc1, ΔEc2, and ΔEc3. That is, the conduction level Ec has no step difference and rises upward to the right relatively smoothly.

FIG. 2B is an energy band diagram of the surge protection element 10 of the present invention when a voltage is applied thereto. Similarly to FIG. 2A, a dash-dotted line indicates the Fermi level Ef of the n-type semiconductor layer 12, and an upper solid line in the n-type semiconductor layer 12 indicates the conduction level Ec also in FIG. 2B. A broken line indicates an energy band diagram of the surge protection element 10 of the present invention in a state in which a voltage is not applied thereto.

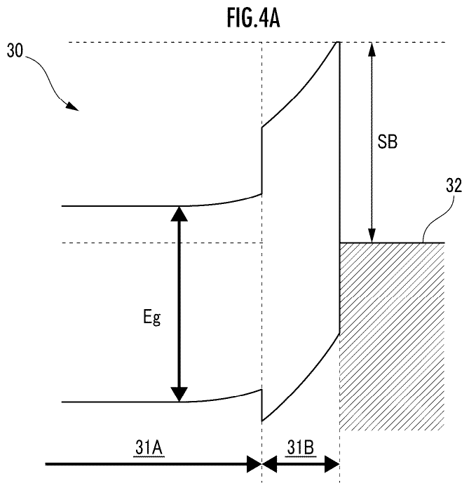

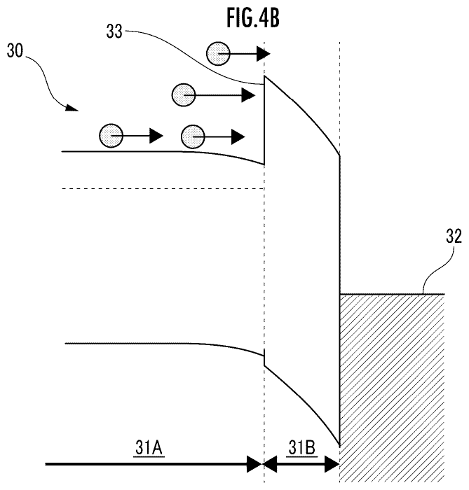

When a voltage is applied to the surge protection element 10 of the present invention as shown in FIG. 2B, the portion composed of the graded composition layer 12B in the n-type semiconductor layer 12 has no step difference as a result of the energy band diagram (see FIG. 2A) before a voltage is applied thereto and falls downward to the right relatively smoothly. That is, the energy barrier 33 produced when a voltage is applied to the conventional semiconductor element 30 as shown in FIG. 4B is not produced. Thus, electrons 20 flow smoothly from the n-type semiconductor layer 12 toward the second electrode 13. That is, an unnecessary current produced by a harmful pulse can be smoothly handled when the n-type semiconductor layer 12 is composed of the graded composition layer 12B.

Although the element A is zinc (Zn), and the element B is magnesium (Mg) in the present embodiment, the element A may be Ga, In, Zn, Mg, Al, Sn, or the like, or may be a combination thereof. The element B may be Mg, Al, Sn, Ga, Zn, or the like, or may be a combination thereof. In the present embodiment, the initial layer 12A is composed of an oxide, but may be composed of a nitride, a composite oxide, or a composite nitride, or may be composed of a combination thereof. In the present embodiment, the graded composition layer 12B and the final layer 12C are composed of a composite oxide, but may be composed of a composite nitride, or may be composed of a combination thereof.

In the present embodiment, the final layer 12C is composed of a composite oxide in which the content ratio of the element B to the element A is 8:2, which is identical to the composition in raw solution in the later stage of growth of the graded composition layer 12B. However, the final layer 12C can be composed of a composite oxide in which the content ratio of the element B to the element A has any value. Alternatively, the final layer 12C may be composed of an oxide of the element B. Still alternatively, the final layer 12C may be composed of a nitride of the element B or a composite nitride containing the element A and the element B, or may be composed of a combination thereof.

Table 1 below is a table collectively showing examples of an element (the element B), the content rate of which is adjusted to relatively increase, among constituting elements of the graded composition layer 12B, a constituent of the initial layer 12A, and a constituent of the final layer 12C.

TABLE 1

| No | Element B | Initial layer | Final layer |
|---|---|---|---|
| 1 | Mg | Zn—O | Zn—Mg—O |
| 2 | Al | Ga—O | Ga—Al—O |
| 3 | Al | Ga—N | Ga—Al—N |
| 4 | Mg | Zn—Mg—O | Zn—Mg—O |
| 5 | Al | Ga—Al—O | Ga—Al—O |
| 6 | Al | Ga—Al—N | Ga—Al—N |
| 7 | Sn | In—O | Sn—O |
| 8 | Sn | In—Sn—O | In—Sn—O |
| 9 | Ga, Zn | In—Ga—Zn—O | In—Ga—Zn—O |

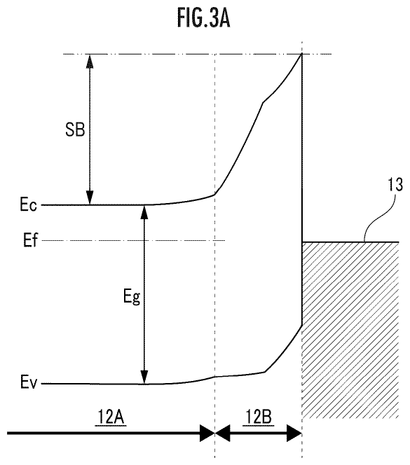

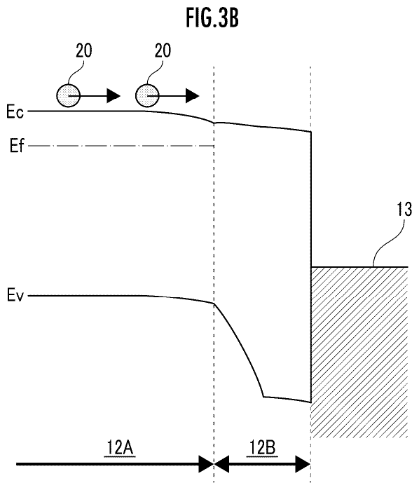

Although the n-type semiconductor layer 12 is composed of three layers of the initial layer 12A, the graded composition layer 12B, and the final layer 12C in the present embodiment, the n-type semiconductor layer 12 may be composed of two layers of the initial layer 12A and the graded composition layer 12B as shown in FIG. 3A and FIG. 3B. In this case, the initial layer 12A is the low-resistance layer, and a terminal end of the graded composition layer 12B on the second electrode side is the high-resistance layer. Even in the case in which the n-type semiconductor layer 12 has such a two-layered structure, the effects obtained by the above-described graded composition layer 12B can be exercised. Alternatively, the n-type semiconductor layer 12 may be composed of two layers of the graded composition layer 12B and the final layer 12C. That is, the graded composition layer 12B may be formed from a terminal end of the n-type semiconductor layer 12 on the first electrode side.

The n-type semiconductor layer 12 may contain a doping material according to necessity. The n-type semiconductor layer 12 can contain at least one of Al, Si, In, Ga, Ge, and Sn as a doping material. When the n-type semiconductor layer 12 contains an appropriate doping element, the bandgap can be adjusted.

The second electrode 13 is joined from above to the n-type semiconductor layer 12 in the designated direction. The second electrode 13 is formed by a publicly-known technique, and a deposition technique such as the deposition method, sputtering method, or the like, for example, is used.

The second electrode 13 is a material that may form a Schottky contact with the n-type semiconductor layer 12, and the material thereof may be composed of an alloy of platinum (Pt) and gold (Au), or one or more elements selected from a metal element group consisting of platinum (Pt), gold (Au), titanium (Ti), nickel (Ni), tungsten (W), molybdenum (Mo), tantalum (Ta), copper (Cu), iron (Fe), silver (Ag), and chromium (Cr), or an alloy thereof. Alternatively, a compound having a metal element such as titanium nitride (TiN) or silver oxide (Ag₂O) may be used for the second electrode 13.

A desired forward rising voltage Vf of the surge protection element 10 can be obtained from a combination of the element that composes the n-type semiconductor layer 12, the element that composes the second electrode 13, and the doping element contained in the n-type semiconductor layer 12.

Next, operation to be performed when a harmful pulse is applied to a semiconductor device including the surge protection element 10 will be described. The surge protection element 10 is connected to a semiconductor circuit connected in the forward direction between a signal line and a ground of the semiconductor device, for example. When a voltage exceeding the forward rising voltage Vf, such as a harmful pulse, is applied to the surge protection element 10, a forward bias current flows in the surge protection element 10 and is grounded (see FIG. 2B). Thus, the semiconductor device including the surge protection element 10 is protected from the harmful pulse.

The forward rising voltage Vf of the surge protection element 10 is set at a value larger than an operating voltage Va of the semiconductor device including the surge protection element 10. Consequently, the surge protection element 10 does not bypass a current when a signal indicating a voltage less than or equal to the forward rising voltage Vf is received. When a harmful pulse larger than the forward rising voltage Vf is applied, the forward bias current flows in the surge protection element 10, and an unnecessary current produced by the harmful pulse is grounded.

As described above in detail, the surge protection element 10 that can smoothly handle an unnecessary current produced by a harmful pulse can be provided.

### REFERENCE SIGNS LIST

10 surge protection element
11 first electrode
12 n-type semiconductor layer
12A initial layer
12B graded composition layer
12C final layer
13 second electrode
20 electron

1. A surge protection element comprising a first electrode, an n-type semiconductor layer, and a second electrode sequentially joined in a designated direction, wherein
a portion at least from any position in the n-type semiconductor layer toward the second electrode in the designated direction is composed of a graded composition layer, whereby in a state in which a voltage is not applied, a bandgap of the portion gradually increases in the designated direction, and part of a conduction level exceeding a Fermi level in the portion gradually increases in the designated direction.

2. The surge protection element according to claim 1, wherein
the graded composition layer of the n-type semiconductor layer is composed of a composite oxide or a composite nitride of at least two elements of an element A and an element B selected from the group consisting of Ga, In, Zn, Mg, Al, and Sn, or a combination thereof, and
a content ratio of the element B to the element A gradually increases in the designated direction.

3. The surge protection element according to claim 1, wherein the n-type semiconductor layer has a thickness of 5 to 1000 nm in the designated direction.

4. The surge protection element according to claim 2, wherein the n-type semiconductor layer has a thickness of 5 to 1000 nm in the designated direction.
